(19) United States
(12) Patent Application Publication
(10) Pub. No.: US 2026/0247979 A1
(43) Pub. Date: Aug. 20, 2026

(54) SEMICONDUCTOR DEVICE INCLUDING MIRRORED DIE PAIRS

(71) Applicant: Sandisk Technologies, Inc., Milpitas, CA (US)

(72) Inventors: Choong Keat Loh, Penang (MY); Weng Khoon Mong, Penang (MY); Huirong Zhang, Shanghai (CN); Au Seong Wong, Penang (MY)

(73) Assignee: Sandisk Technologies, Inc., Milpitas, CA (US)

(21) Appl. No.: 19/468,183

(22) Filed: Feb. 3, 2026

Related U.S. Application Data
(60) Provisional application No. 63/760,719, filed on Feb. 20, 2025.

(51) Int. Cl. H10W 42/00; H10W 70/60; H10W 72/00; H10W 90/20

(52) U.S. Cl. CPC H10W 42/121; H10W 70/614; H10W 72/823; H10W 90/271

(57) ABSTRACT

A semiconductor device includes one or more back-to-back mirrored die pairs (BMPs). Each BMP includes first and second memory dies, joined with their respective back (inactive) surfaces bonded to each other using an adhesive. Die bond pads may be formed on exposed (active) top and bottom surfaces of the BMP. A BMP may be encapsulated in a mold compound around its edges. In order to route electrical signals between the first and second dies of a BMP, conductive columns may be formed in the mold compound around one or more of the edges of the BMP, and an RDL (redistribution layer) may be formed on the exposed top and bottom surfaces of the BMP.

### CLAIM OF PRIORITY

The present application claims priority from U.S. Provisional Patent Application No. 63/760,719, entitled “SEMICONDUCTOR DEVICE INCLUDING MIRRORED DIE PAIRS,” filed Feb. 20, 2025, which is incorporated by reference herein in its entirety.

### BACKGROUND

The strong growth in demand for portable consumer electronics is driving the need for high-capacity storage devices. Non-volatile semiconductor memory devices, such as flash memory storage cards, are widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs, cellular telephones and solid state drives (SSDs).

Artificial intelligence (AI) and machine learning (ML) applications demand advanced memory and computing solutions with high performance, low power dissipation, low latency, and high bandwidth to support intensive read and write operations during the training and inference phases. To meet these requirements, 3D BiCS (Bit Cost Scalable) technology has emerged as a viable solution, offering rapid scaling to achieve higher storage capacity per die.

Traditionally, multi-die stacking of, for example, BiCS memory dies using wire bonding has been employed to increase storage capacity. However, this approach suffers from significant drawbacks, including limitations in semiconductor die thicknesses. In particular, given the ever-present drive to provide greater storage capacity in a smaller form factor, semiconductor devices are made as thin as possible, currently about 36 microns (μm) or smaller. However, mechanical factors such as die warping, chipping and/or cracking during semiconductor package fabrication are proving a barrier to further reduction in thickness of semiconductor dies.

To address these challenges, a mirrored die pair bonding method has been developed, where two memory wafers are bonded with their active surfaces (containing the integrated circuits and the die bond pads) face-to-face. The face-to-face bonding significantly reduces warping, and allows the wafers to be further thinned without chipping. Moreover, the die pairs effectively double the storage capacity. It is known to route high-voltage, logic, I/O, and other electrical signals in a mirrored die pair using TSVs (through silicon vias) which extend through the entire thickness of the mirrored die pairs. However, TSVs are difficult to form and add expense to the overall fabrication process.

### DESCRIPTION OF THE DRAWINGS

FIG. 1 is a flowchart for forming a semiconductor memory die according to embodiments of the present technology.

FIG. 2 is a top view of a semiconductor wafer, and a semiconductor die therefrom, according to embodiments of the present technology.

FIG. 3 is a cross-sectional edge view of a semiconductor die of the wafer according to embodiments of the present technology.

FIG. 4 is a cross-sectional edge view of a semiconductor die of the wafer after thinning according to embodiments of the present technology.

FIG. 5 is a flowchart for assembling a BMP module according to embodiments of the present technology.

FIG. 6 is a cross-sectional edge view of the first and second semiconductor dies affixed back-to-back to form a BMP according to embodiments of the present technology.

FIG. 7 is a cross-sectional edge view of a BMP positioned in a mold chase with conductive columns along one or more edges according to embodiments of the present technology.

FIG. 8 is a cross-sectional edge view of a molded BMP according to embodiments of the present technology.

FIG. 9 is a cross-sectional edge view of a molded BMP with an RDL on a first active surface of the BMP according to embodiments of the present technology.

FIG. 10 is a cross-sectional edge view of a molded BMP with a second surface thinned to expose a second active surface of the BMP according to embodiments of the present technology.

FIG. 11 is a cross-sectional edge view of a molded BMP with an RDL on both first and second active surfaces to form a finished BMP module according to embodiments of the present technology.

FIG. 12 is a top view of a BMP module according to embodiments of the present technology.

FIG. 13 is a bottom view of a BMP module according to embodiments of the present technology.

FIG. 14 is a cross-sectional edge view of a BMP module including solder bumps or solder balls to electrically couple the BMP module to other modules or components according to embodiments of present technology.

FIG. 15 is a cross-sectional edge view of a completed BMP semiconductor device including a stack of BMP modules according to embodiments of present technology.

FIG. 16 is a cross-sectional edge view of multiple BMPs being formed together on a panel according to embodiments of the present technology.

FIG. 17 is a cross-sectional edge view of multiple BMPs operating as a single BMP semiconductor device according to an alternative embodiment of the present technology.

### DETAILED DESCRIPTION

The present technology will now be described with reference to the figures, which in embodiments, relate to a semiconductor device comprising one or more back-to-back mirrored die pairs, referred to herein as BMPs. Each BMP is comprised of first and second memory dies, bonded with their respective back (inactive) surfaces bonded to each other using an adhesive. Die bond pads may be formed on exposed (active) top and bottom surfaces of the BMP. A BMP may be encapsulated in a mold compound around its edges.

In order to route electrical signals between the first and second dies of a BMP, conductive columns may be formed in the mold compound around one or more of the edges of the BMP, and an RDL (redistribution layer) may be formed on the exposed top and bottom surfaces of the BMP. The conductive columns and a first set of traces in the RDL on the top and bottom surfaces electrically couple the die bond pads of the first and second memory dies to each other. The RDL on the top and bottom surfaces further includes a second set of traces electrically coupled to the die bond pads on the top and bottom surfaces to allow fanout electrical coupling of the die bond pads to RDL contact pads on the top and bottom surfaces of the BMP. Conductive bumps may be formed on the RDL contact pads to allow mounting of a BMP semiconductor device to a host device, and to allow stacking of multiple BMP semiconductor devices.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.15 mm, or alternatively, ±2.5% of a given dimension.

For purposes of this disclosure, a physical or electrical connection may be a direct connection or an indirect connection (e.g., via one or more other parts). In some cases, when a first element is referred to as being connected, affixed, mounted or coupled to a second element (either physically or electrically), the first and second elements may be directly connected, affixed, mounted or coupled to each other or indirectly connected, affixed, mounted or coupled to each other (either physically or electrically). When a first element is referred to as being directly connected, affixed, mounted or coupled to a second element, then there are no intervening elements between the first and second elements (other than possibly an adhesive or melted metal used to connect, affix, mount or couple the first and second elements).

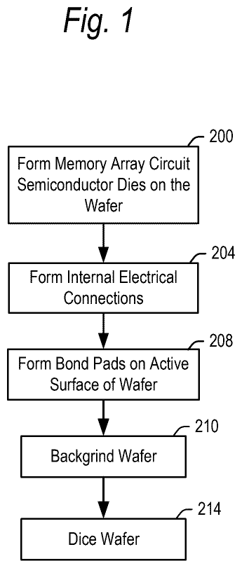

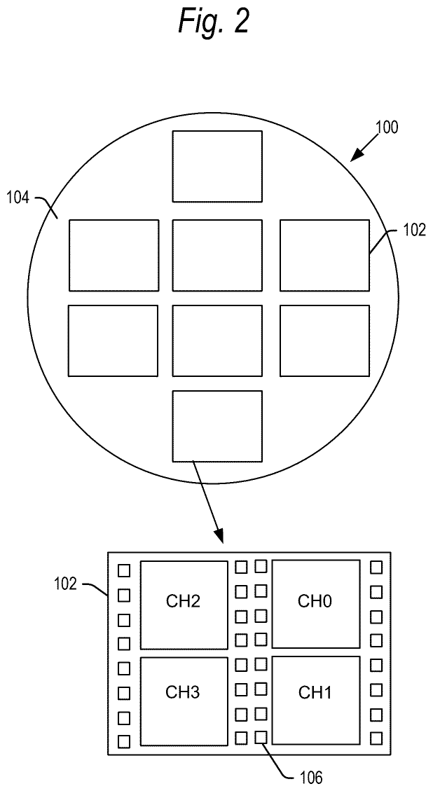

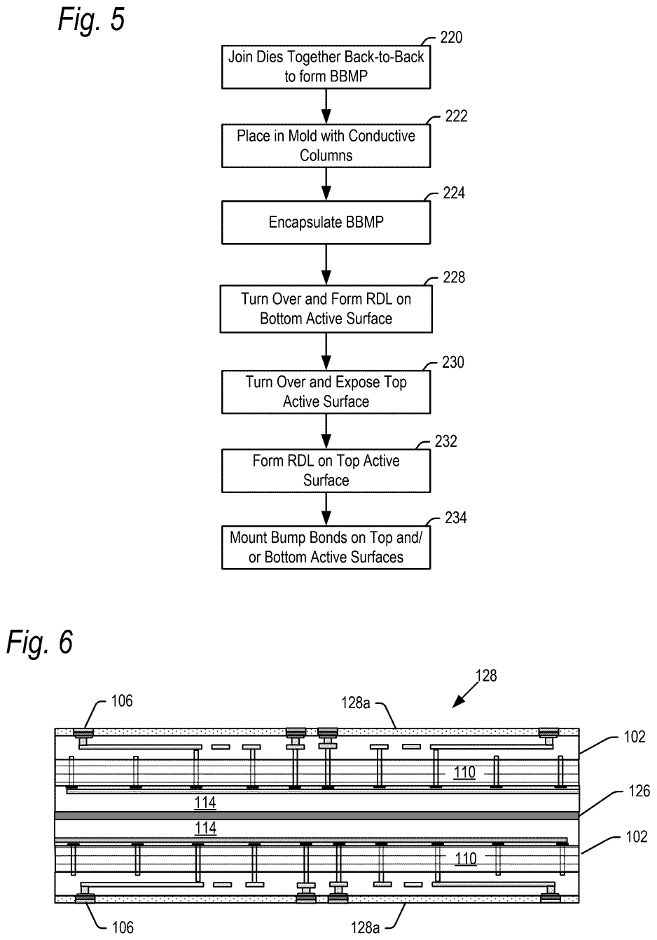

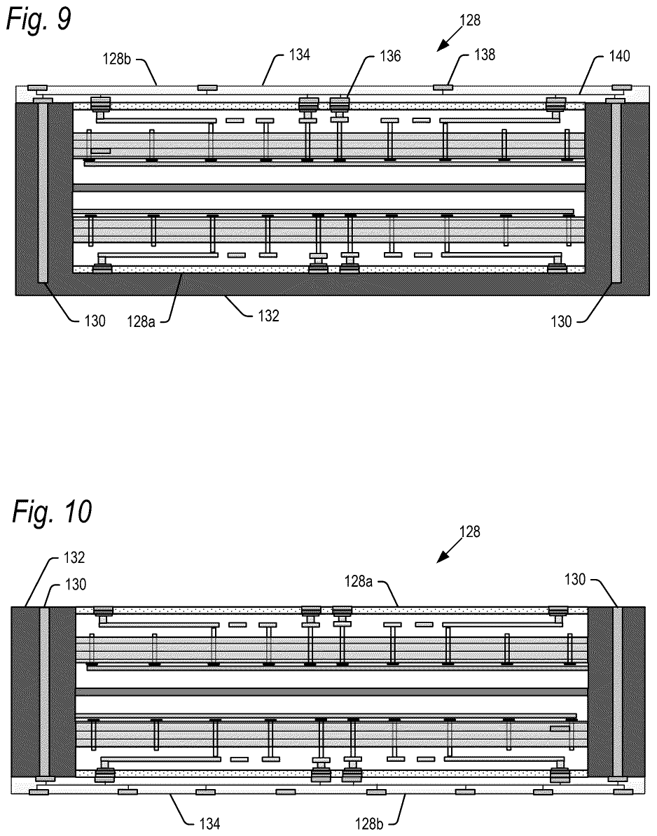

An embodiment of the present technology will now be explained with reference to the flowchart of FIGS. 1 and 5, and the views of FIGS. 2-4 and 6-17. In step 200, a semiconductor wafer 100 may be processed into a number of semiconductor dies 102, such as for example memory array semiconductor dies, as shown in FIG. 2. The semiconductor wafer 100 may start as an ingot of wafer material which may be monocrystalline silicon grown according to either a Czochralski (CZ) or floating zone (FZ) process. However, wafer 100 may be formed of other materials and by other processes in further embodiments.

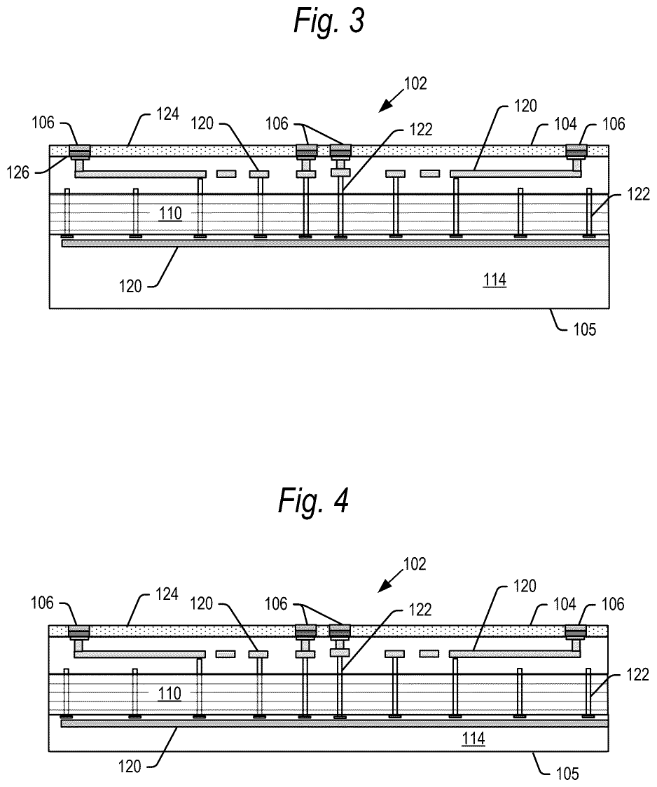

The semiconductor wafer 100 may be cut from the ingot and polished on both the first major planar surface 104, and second major planar surface 105 (FIG. 3) opposite surface 104, to provide smooth surfaces. The first major surface 104 may undergo various processing steps to divide the wafer 100 into the respective semiconductor dies 102, and to form integrated circuits of the respective semiconductor dies 102 on and/or in the first major surface 104. FIG. 2 further shows detail of a single semiconductor die 102 including a flash memory array each having four separate (independently accessible) memory planes, or channels CH0-CH3. Having separate, independently accessible memory planes increases the bandwidth for dies 102, but separate memory planes may be omitted in further embodiments. The single die 102 of FIG. 2 further incudes a pattern of die bond pads 106 as explained below.

As shown in the cross-sectional edge view of FIG. 3, the processing of wafer 100 in step 200 may include the formation of integrated circuit memory cell array 110 formed in a dielectric substrate including layers 114. A reticle may be used to transfer an integrated circuit pattern for each semiconductor die 102 in a photolithography process. The patterned wafer can then undergo various processes such as etching, ion implantation, and deposition to create the actual semiconductor components and interconnections needed to build the integrated circuits of a semiconductor die 102. In embodiments, the integrated circuits may be a memory cell array 110 formed as a 3D stacked memory structure having strings of memory cells formed into layers. However, it is understood that the semiconductor die 102 may be processed to include integrated circuits other than a 3D stacked memory structure. As noted above, in embodiments, the memory array 110 on each semiconductor die 102 may comprise for separate memory planes CH0-CH3.

After formation of the memory cell array 110, internal electrical connections may be formed within the semiconductor die 102 in step 204. The internal electrical connections may include multiple layers of metal interconnects 120 and vias 122 formed sequentially through layers of the substrate 114. As is known in the art, the metal interconnects 120 and vias 122 may be formed for example by damascene processes a layer at a time using photolithographic and thin-film deposition processes. The photolithographic processes may include for example pattern definition, plasma, chemical or dry etching and polishing. The thin-film deposition processes may include for example sputtering and/or chemical vapor deposition. The metal interconnects 120 may be formed of a variety of electrically conductive metals including for example copper and copper alloys as is known in the art, and the vias 122 may be lined and/or filled with a variety of electrically conductive metals including for example tungsten, copper and copper alloys as is known in the art. As seen for example in FIG. 3, the metal interconnects 120 and vias 122 may be formed between the memory cell array 110 and die bond pads 106 to carry signals to and from the memory cell array 110. A passivation layer 124 may be formed on top of the metal interconnect layers 120.

In step 208, die bond pads 106 may be formed on the first (active) major planar surface 104 of the semiconductor dies 102. As shown in FIGS. 2 and 3, these pads may be formed on top of vias 122 and may be used to transfer signals to and from the semiconductor die 102. The die bond pads 106 may be etched into the passivation layer 124, and each die bond pad 106 may be formed over a liner 126. As is known in the art, the die bond pads 106 may be formed for example of copper, aluminum and alloys thereof, and the liner 126 may be formed for example of a titanium/titanium nitride stack such as for example Ti/TiN/Ti, though these materials may vary in further embodiments. The die bond pads 106 and liner 126 may be applied by vapor deposition and/or plating techniques. The integrated circuit memory arrays 110 may be electrically connected to the die bond pads 106 by the metal interconnects 120 and vias 122.

In step 210, the first (active) surface 104 of the wafer 100 may be supported on a temporary carrier (not shown) and the second (inactive) surface 105 may be thinned in a backgrind process to a final thickness of wafer 100 (shown in FIG. 4).

FIG. 2 shows an example pattern of semiconductor dies 102 on wafer 100. However, the patterns and number of semiconductor dies 102 shown on wafer 100 in FIG. 2 is for illustrative purposes, and wafer 100 may include more or less semiconductor dies 102 than are shown in further embodiments, and in different patterns. Similarly, the pattern and number of pads 106 on the semiconductor die 102 shown in FIGS. 2-4 are shown for illustrative purposes. Each first die 102 may include more or less die bond pads 106 than are shown in further embodiments, and may include various other patterns and densities of pads 106.

Although FIGS. 3-4 show individual dies 102 for simplicity, at this stage of fabrication, the dies 102 are still part of the wafer 100. After backgrind of the inactive surface 105, the wafer 100 may be supported on a dicing tape, and the wafer 100 may be diced to form individual memory dies 102 in step 214. The wafer 100 may be diced into individual semiconductor dies 102 using for example stealth laser dicing. Saw blades and other traditional methods may be used in further embodiments. After dicing, the dicing tape may be spread apart to facilitate picking of the dies 102 from the dicing tape by a pick and place robot (not shown).

FIG. 5 is a flowchart showing assembly of the dies 102 into a BMP assembly. In step 220, a pair of semiconductor dies 102 are bonded to each other back-to-back to form a back-to-back mirrored die pair (BMP) 128. ‘Back-to-back’ in this instance indicates that the inactive surfaces 105 of a pair of semiconductor dies 102 are mated together and bonded with an adhesive 126. The adhesive may for example be a standard DAF (die attach film) available for example from Henkel Corporation, having offices in Irvine, CA. The BMP 128 has a first, or top, surface 128a and a second, or bottom, surface 128b.

In further embodiments, BMPs 128 may be formed at the wafer stage. In this embodiment, a pair of wafers 100 may be mounted to each other back-to-back and bonded with an adhesive. After bonding, the individual BMPs 128 may be diced from the paired wafers.

The bonding of dies 102 together in a mirrored configuration provides a number of advantages. First, the mirrored bonding of dies 102 results in an offsetting of coefficients of thermal expansion, thereby reducing or preventing warping of the BMP 128. Further, as the thickness of the BMP is double that of the individual dies, the individual dies 102 may be made thin which the resulting BMP 128 is sturdy. Each of the dies 102 in an BMP 128 may be 15 μm to 25 μm, though they may be thinner or thicker than that in further embodiments.

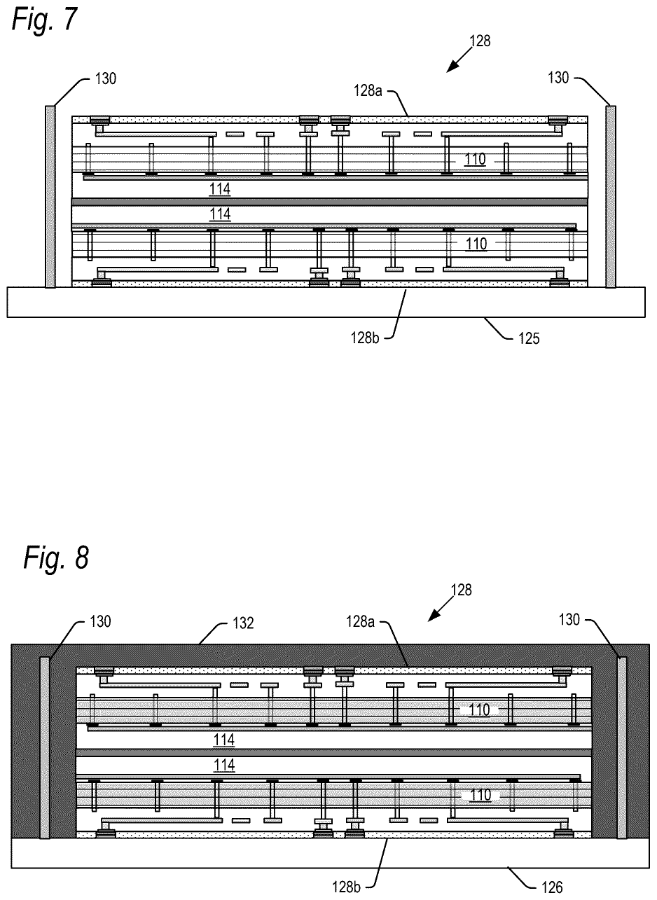

After formation of the BMP 128, the BMP 128 may be placed in a mold chase in step 222 including bottom plate 125 as shown in FIG. 7. A number of conductive columns 130 are also placed in the mold chase around one or more edges of the BMP 128. The columns may have a diameter of between 50 μ and 500 μm, though it may be thinner or thicker than that in further embodiments. Each column 130 may have a length at least as tall as a thickness of the BMP 128. The columns 130 may be formed of an electrical conductor such as copper, aluminum or alloys thereof. The number of columns 130 may vary, but in embodiments, may be at least as great as the number die bond pads 106 on active surfaces 128a, 128b. The columns may be positioned around one, two adjoining or opposed sides, three sides or all four sides. The columns 130 may be positioned directly adjacent the BMP 128, but spaced enough so as to have no capacitive or other electrical impact on the BMP 128 as a result of current flow through the columns.

In step 224 the BMP 128 and columns 130 may be encapsulated in mold compound 132 as shown in FIG. 8. Mold compound 132 may be injection molded around BMP 128. Other encapsulation processes may be used, including for example FFT (Flow Free Thin) compression molding, in further embodiments. Mold compound 132 may include for example solid epoxy resin, Phenol resin, fused silica, crystalline silica, carbon black and/or metal hydroxide. Such mold compounds are available for example from Sumitomo Corp. and Nitto-Denko Corp., both having headquarters in Japan. Other encapsulants from other manufacturers are contemplated.

The bottom active surface 128b may be flush against the bottom mold plate 125 and, as such, may be devoid of mold compound 132. In step 228, the BMP 128 may be removed from the mold chase, turned over, and an RDL (redistribution layer) 134 may be formed on the bottom active surface 128b. The RDL 134 may comprise an interior surface (against the BMP 128) with a number of interior RDL pads 136, an exterior surface (facing away from the BMP 128) with a number of exterior RDL pads 138, and electrical traces 140 connecting the interior and exterior RDL pads 136, 138.

RDL 134 has a first group of electrical connections electrically coupling the die bond pads 106 on the bottom active surface 128b to the exterior RDL pads 138. In this first group of electrical connections, interior RDL pads 136 mounted to die bond pads 106 are coupled to exterior RDL pads 138 by a first set of traces 140. RDL 134 further has a second group of electrical connections electrically coupling the die bond pads 106 on the bottom active surface 128b to the conductive columns 130 at the bottom active surface 128b. In this second group of electrical connections, interior RDL pads 136 mounted to die bond pads 106 are coupled to interior RDL pads 136 on conductive columns 132 by a second set of traces 140.

The RDL 134 may be affixed to the bottom active surface 128b of BMP 128 by an adhesive on the interior surface of the RDL 134. The interior RDL pads 136 may be electrically coupled to the die bond pads 106 and the conductive columns for example by Cu-to-Cu bonding. A solder bump may also be applied over the die bond pads 106 and/or the conductive columns 132 to facilitate the bond.

Once the RDL 134 is formed on the bottom active surface 128b, the BMP 128 may be flipped over and supported on a temporary carrier (not show) so that the mold compound 132 over the top active surface 128a may be removed in step 230. The mold compound on the top active surface 128a may be removed by a number of methods including grind and polish, or a chemical etch. Once completed, the top active surface 128a is exposed as shown in FIG. 10. The grind/etch step 230 also removes the mold compound 132 over the conductive columns 132 terminating at the top active surface 128a so that the top of the mold compound 132 at the edges of the BMP 128 are coplanar with the exposed active top surface 128a. Where the conductive columns 132 were initially longer than the thickness of BMP 128, the grind/etch step 230 leave the ends of the conductive columns 132 coplanar with the exposed active top surface 128a.

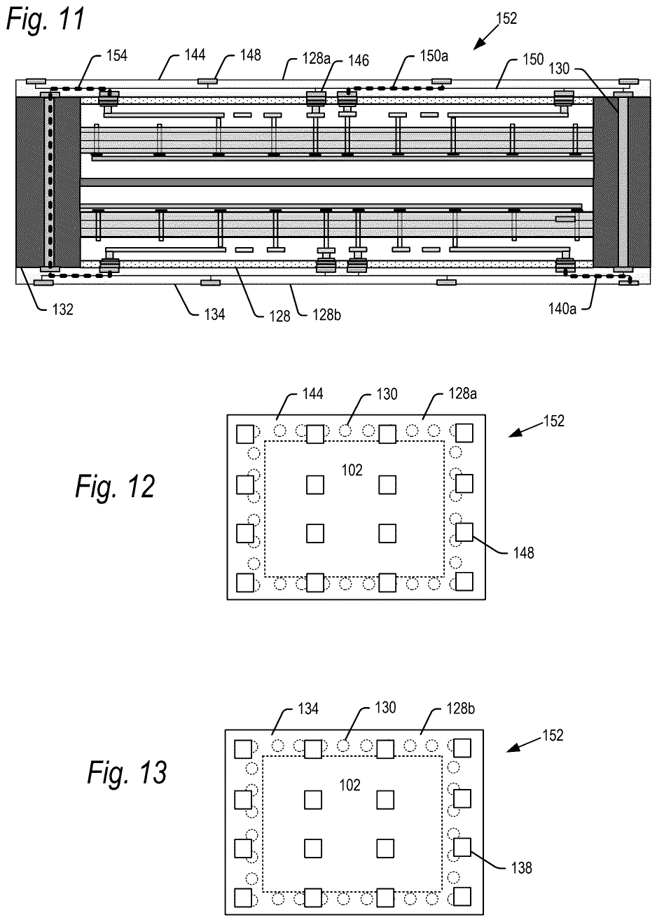

In step 232, an RDL 144 may be formed on the top active surface 128a as shown in the cross-sectional edge view of FIG. 11. FIG. 11 shows a completed BMP module 152 with all electrical connections made to and from the BMP 128. The RDL 144 may comprise an interior surface (against the BMP 128) with a number of interior RDL pads 146, an exterior surface (facing away from the BMP 128) with a number of exterior RDL pads 148, and electrical traces 150 connecting the interior and exterior RDL pads 146, 148.

RDL 144 has a first group of electrical connections electrically coupling the die bond pads 106 on the top active surface 128a to the exterior RDL pads 148. In this first group of electrical connections, interior RDL pads 146 mounted to die bond pads 106 are coupled to exterior RDL pads 148 by a first set of traces 150. RDL 144 further has a second group of electrical connections electrically coupling the die bond pads 106 on the top active surface 128a to the conductive columns 130 at the top active surface 128a. In this second group of electrical connections, interior RDL pads 146 mounted to die bond pads 106 are coupled to interior RDL pads 146 on conductive columns 132 by a second set of traces 150.

The RDL 144 may be affixed to the top active surface 128a of BMP 128 by an adhesive on the interior surface of the RDL 144. The interior RDL pads 146 may be electrically coupled to the die bond pads 106 and the conductive columns for example by Cu-to-Cu bonding. A solder bump may also be applied over the die bond pads 106 and/or the conductive columns 132 to facilitate the bond.

The RDLs 134, 144 may serve at least two purposes. First, the RDL 134 effectively redistributes the bond pads 106 on bottom active surface 128b to the exterior RDL pads 138. See for example path 140a in FIG. 11. Likewise, the RDL 144 effectively redistributes the bond pads 106 on top active surface 128a to the exterior RDL pads 148. See for example path 150a in FIG. 11. While design constraints may require die bond pads 106 to be placed in particular, possibly suboptimal, positions, the exterior RDL pads 138, 148 on respective surfaces of the BMP 128 may be evenly spaced out or otherwise placed in optimal positions. Moreover, as the exterior RDL surfaces are larger than the surfaces 128a, 128b of BMP 128, the RDLs allow the exterior RDL pads 138, 148 to “fanout” relative to the die bond pads 106.

FIG. 12 is a top view of a BMP module 152 showing one example of a possible fanout distribution of exterior RDL pads 148 on the top surface 128a. The upper die 102 and one example of a distribution of conductive columns 130 is shown in phantom in FIG. 12 beneath the RDL 144. It is understood that the distribution of exterior RDL pads 148, and the distribution of conductive columns 130, may vary in further embodiments.

FIG. 13 is a bottom view of a BMP module 152 showing one example of a possible fanout distribution of exterior RDL pads 138 on the bottom surface 128b. The lower die 102 and one example of a distribution of conductive columns 130 is shown in phantom in FIG. 13 beneath the RDL 134. It is understood that the distribution of exterior RDL pads 138, and the distribution of conductive columns 130, may vary in further embodiments.

A second function of RDLs 134, 144 and conductive columns 130 is to electrically couple corresponding bond pads 106 on the top and bottom surfaces 128a, 128b. In embodiments, corresponding bond pads on the top and bottom dies 102 comprise a single channel for read/write operations, and may be electrically coupled to each other. While this function may be accomplished by complex and expensive TSVs in the prior art, the present technology accomplishes this through the RDLs 134, 144 and the vertical columns 130. See for example path 152 in FIG. 11 electrically coupling the corresponding bond pads on the top and bottom memory dies 102 to each other. Thus, the RDLs 134, 144 and the vertical columns comprise electrical connectors that electrically couple corresponding die bond pads on the active surfaces of the first and second semiconductor dies 102 without passing through the first semiconductor die or second semiconductor die.

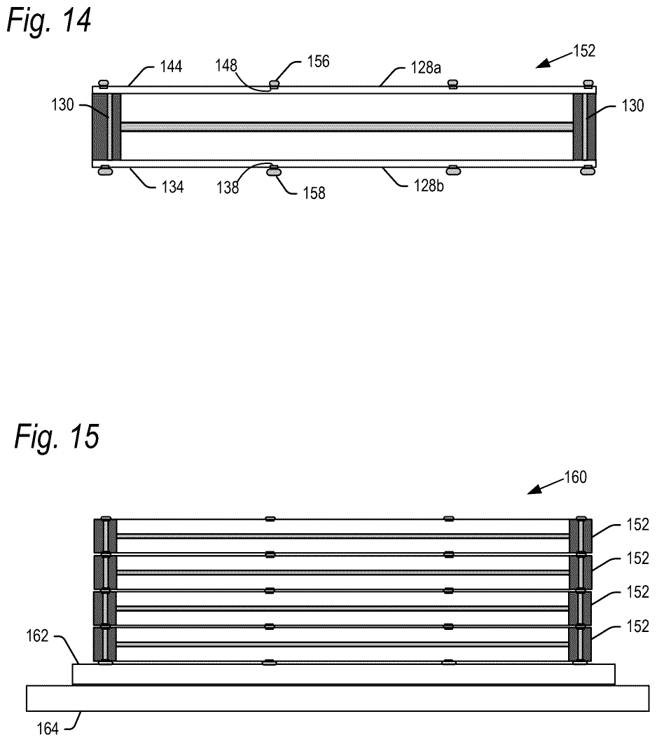

In step 234, electrical connectors may be formed on the top and/or bottom surfaces of BMP module 152 to allow electrical connection of the BMP module 152 to other BMP modules and components. Referring now to the cross-sectional edge view of FIG. 14, electrical connectors 156 may be formed on each of the exterior RDL pads 148 on the RDL 144. The electrical connectors 156 may for example be solder bumps. Electrical connectors 158 may be formed on each of the exterior RDL pads 138 on the RDL 134. The electrical connectors 158 may be solder bumps (identical to solder bumps 156). Where the BMP module 152 is to be mounted directly to a host device such as a printed circuit board, the electrical connectors 158 may be solder balls.

FIG. 15 is a cross-sectional edge view of a BMP semiconductor device 160 comprising a number of BMP modules 152 stacked on top of each other. In particular, as noted above, given the flexibility in the positioning of exterior RDL pads 138, 148 on the upper and lower surfaces of the BMP module 152, the exterior RDL pads 148 may be positioned in the same positions (from a top view) on surface 128a as the exterior RDL pads 138 on surface 128b. Thus, the electrical connectors 156, 158 may be used to bond a number of BMP modules 152 together in a stacked and vertically aligned position, thus taking up a minimal footprint. While FIG. 15 shows four such stacked BMP modules 152, there may be 1, 2, 4, 8, 16, 32 or 64 such stacked BMP modules 152. There may be other numbers of stacked BMP modules 152 in further embodiments.

FIG. 15 shows the stack of BMP modules 152 mounted on top of a controller 162. The controller 162 may be an ASIC or other controller for controlling read/write operations and other signal exchanges with the stack of BMP modules 152. Other types of specialized controllers 162 may be used, including for example Artificial Intelligence (AI) controllers or graphics processing units.

The controller 162 is in turn shown mounted on a host device such as a printed circuit board (PCB) 164. In further embodiments, the stack of BMP modules 152 may be mounted directly on top of the PCB 164, and the controller 162 may be mounted next to the stack of BMP modules 152, or omitted entirely.

In embodiments described above, the conductive columns 130 are formed in place during the encapsulation process. In a further embodiment, the conductive columns may be omitted during the encapsulation process. In such embodiments, after the encapsulation process and before formation of the RDLs 134, 144, holes may be drilled top down through the mold compound 132 around one or more edges of the BMP 128. These holes may then be plated and then filled with an electrical conductor such as copper, aluminum, or alloys thereof. In this embodiment, the conductive columns 132 comprise vias.

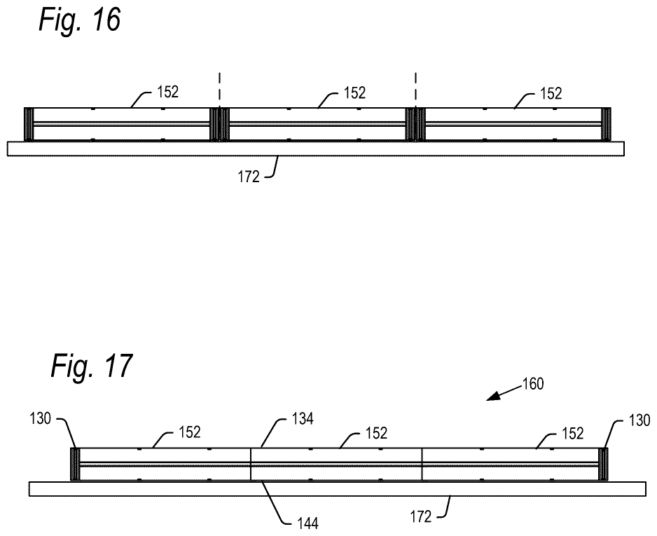

FIGS. 7 and 8 show a single BMP 128 being encapsulated on mold plate 125. However, as shown in FIG. 16, a number of BMPs 128 may be fabricated together on a panel 170 for economies of scale. RDLs 134 and 144 may be applied across the multiple BMPs 128. After completion of the assembly process, the individual BMP modules 152 may be separated from panel 170 and cut along the dashed lines in FIG. 16 to create the individual BMP modules 152.

FIG. 17 shows a further embodiment of the present technology. FIG. 17 is similar to FIG. 16, but multiple BMP modules 152 operate together as a single BMP semiconductor device 160. In this embodiment, the BMP modules 152 may be formed on the carrier 172, but they do not get singulated from each other (or at least multiple BMP modules 152 are left attached to each other after singulation). In this embodiment, arrays of BMP modules may be left intact with each other and operate together as a single BMP semiconductor device 160. The size of the array may vary in embodiments, including for as for example 1×2, 2×2, 2×4, 3×3, etc.

In the embodiment of FIG. 17, the conductive columns 130 may be provided around one or more edges around the outer periphery of the BMP semiconductor device 160 comprising the array of BMP modules 152. In this embodiment, the conductive columns 130 may be omitted from between adjacent BMP modules 152. In this embodiment, the RDL 134 may extend over the entire upper surface of the BMP semiconductor device 160, and the RDL 144 may extend over the entire lower surface of the BMP semiconductor device 160. As described above, the RDLs 134, 144 in this embodiment may redistribute the die bond pads to RDL pads 138, 148 on exterior surfaces of the RDLs 134, 144. The RDL 134 can redistribute any die bond pad in the array to any RDL pad 138 across the exterior surface, and the RDL 144 can redistribute any die bond pad in the array to any RDL pad across the exterior surface. The RDLs 134, 144, together with conductive columns 130, further transfer signals between the top and bottom surfaces of the BMP semiconductor device 160. In further embodiments of the BMP semiconductor device 160 of FIG. 17, the conductive columns 130 may be provided between adjacent BMP modules 152 in the array.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. A semiconductor module, comprising:
a first semiconductor die, comprising:
a first active surface comprising one or more die bond pads, and
a second inactive surface opposed to the first active surface;
a second semiconductor die, comprising:
a third active surface comprising one or more die bond pads, and
a fourth inactive surface opposed to the third active surface, wherein the first and second semiconductor dies are joined with the second inactive surface of the first semiconductor die bonded to the fourth inactive surface of the second semiconductor die; and
electrical connectors for electrically coupling a first die bond pad on the first active surface to a corresponding second die bond pad on the third active surface without passing through the first semiconductor die or second semiconductor die.

2. The semiconductor module of claim 1, wherein the electrical connectors comprise redistribution layers (RDLs) on the first and third active surfaces of the first and second semiconductor dies.

3. The semiconductor module of claim 2, wherein the RDLs on the first and third active surfaces of the first and second semiconductor dies further redistribute and fanout the die bond pads onto a pattern of exterior RDL pads on exterior surfaces of the RDL layers.

4. The semiconductor module of claim 3, the pattern of exterior RDL pads of the RDL on the first active surface of the first semiconductor die match the pattern of exterior RDL pads of the RDL on the third active surface of the second semiconductor die.

5. The semiconductor module of claim 1, wherein the electrical connectors comprise conductive columns around one or more edges of the first and second semiconductor dies.

6. The semiconductor module of claim 1, further comprising mold compound around one or more edges of the first and second semiconductor dies.

7. The semiconductor module of claim 6, wherein the electrical connectors comprise conductive columns within the mold compound around the one or more edges of the first and second semiconductor dies.

8. The semiconductor module of claim 7, wherein the conductive columns comprise metal columns embedded within the mold compound.

9. The semiconductor module of claim 7, wherein the conductive columns comprise vias formed in the mold compound.

10. The semiconductor module of claim 1, wherein the electrical connectors electrically coupling the first die bond pad to the corresponding second die bond pad are disposed entirely outside the silicon material of the first and second semiconductor dies and do not extend through either semiconductor die.

11. The semiconductor module of claim 1, wherein bonding the dies in a back-to-back mirrored configuration reduces warpage during subsequent encapsulation and redistribution layer formation.

12. A semiconductor device, comprising:
a semiconductor module, comprising:
a first semiconductor die, comprising:
a first active surface comprising one or more die bond pads, and
a second inactive surface opposed to the first active surface;
a second semiconductor die, comprising:
a third active surface comprising one or more die bond pads, and
a fourth inactive surface opposed to the third active surface, wherein the first and second semiconductor dies are joined with the second inactive surface of the first semiconductor die bonded to the fourth inactive surface of the second semiconductor die; and
electrical connectors for electrically coupling a first die bond pad on the first active surface to a corresponding second die bond pad on the third active surface, the electrical connectors comprising conductive columns around the one or more edges of the first and second semiconductor dies; and
a controller die for controlling read/write operations of the semiconductor module.

13. The semiconductor device of claim 12, wherein the electrical connectors further comprise redistribution layers (RDLs) on the first and third active surfaces of the first and second semiconductor dies.

14. The semiconductor device of claim 12, further comprising mold compound around one or more edges of the first and second semiconductor dies.

15. The semiconductor device of claim 14, wherein the conductive columns are provided within the mold compound around the one or more edges of the first and second semiconductor dies.

16. The semiconductor module of claim 12, wherein the conductive columns comprise metal columns embedded within the mold compound.

17. The semiconductor device of claim 12, wherein the conductive columns comprise vias formed in the mold compound.

18. The semiconductor device of claim 12, wherein a plurality of the semiconductor modules are vertically stacked and electrically interconnected through aligned exterior redistribution layer (RDL) pads on opposing surfaces of adjacent semiconductor modules, such that the stacked semiconductor modules occupy a common footprint.

19. The semiconductor device of claim 12, wherein bonding the dies in a back-to-back mirrored configuration reduces warpage during subsequent encapsulation and redistribution layer formation.

20. A semiconductor module, comprising:
a first semiconductor die, comprising:
a first active surface comprising one or more die bond pads, and
a second inactive surface opposed to the first active surface;
a second semiconductor die, comprising:
a third active surface comprising one or more die bond pads, and
a fourth inactive surface opposed to the third active surface, wherein the first and second semiconductor dies are joined with the second inactive surface of the first semiconductor die bonded to the fourth inactive surface of the second semiconductor die; and
means for electrically coupling a first die bond pad on the first active surface to a corresponding second die bond pad on the third active surface without passing through the first semiconductor die or second semiconductor die.
